(19) United States
(12) Patent Application Publication
(10) Pub. No.: US 2009/0168330 A1
(43) Pub. Date: Jul. 2, 2009

(54) ELECTRONIC DEVICE WITH AIRFLOW GUIDING DUCT

(75) Inventors: YANG LI, Shenzhen City (CN); YU-HSU LIN, San Jose, CA (US); JENG-DA WU, Tu-Cheng (TW); LEI GUO, Shenzhen City (CN); LIANG-LIANG CAO, Shenzhen City (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/118,758

(22) Filed: May 12, 2008

(30) Foreign Application Priority Data
Dec. 27, 2007 (CN) 200720201791.X

(51) Int. Cl. G06F 1/20; H05K 7/20

(52) U.S. Cl. 361/679.47; 361/690; 361/695; 361/697

(57) ABSTRACT

An electronic device includes an enclosure (30), a circuit board (40), and an airflow guiding duct (10). The enclosure includes a bottom wall (31) and a rear wall (32) perpendicular to the bottom wall. The circuit board is mounted on the bottom wall of the enclosure. The circuit board includes a first heat generating element (41) and a second heat generating element (42) near to the first heat generating element. The airflow guiding duct includes two side panels (11) and a connecting panel (13) connecting a pair of side edges (112) of the two side panels. A first opening (17) is defined by a lower edge (131) of the connecting panel and lower edges (111) of the two side panels and corresponding to the first heat generating element. The lower edges of the two side panels and the lower of the connecting panel are in the same plane. The first opening is a predetermined distance from the circuit board and the airflow guiding duct is capable of allowing air flow from different directions.

### BACKGROUND

1. Field of the Invention

The present invention relates to electronic devices, particularly to an electronic device with an airflow guiding duct for heat dissipating modules therein.

2. Description of Related Art

A heat dissipating module is generally mounted on a motherboard of an electronic device, such as a computer or a server, for dissipating heat generated by electronic components in the electronic device. With the development of the computer industry, heat generated by the electronic components becomes greater due to faster speeds of the computers or servers. The conventional heat dissipating module cannot satisfy the requirements of current computer or server systems by itself, so an airflow guiding duct is usually mounted above the heat dissipating module on the motherboard, for guiding airflow, increasing effectiveness of heat dissipation. Conventionally, an airflow guiding duct includes an input opening for air flowing into the airflow guiding duct and an output opening for air flowing out of the airflow guiding duct. There are often many components disposed on the motherboard around the airflow guiding duct but not around the input opening. The plane of the input opening is often perpendicular to the motherboard and air mainly flows into the airflow guiding duct through the input opening, so heat generated by the components around the input opening cannot be dissipated efficiently due to lack of airflow, which may cause some of the components to breakdown.

What is needed, therefore, is an electronic device with an airflow guiding duct that dissipates heat efficiently.

### SUMMARY

An electronic device includes an enclosure, a circuit board, and an airflow guiding duct. The enclosure includes a bottom wall and a rear wall perpendicular to the bottom wall. The circuit board is mounted on the bottom wall of the enclosure. The circuit board includes a first heat generating element and a second heat generating element near to the first heat generating element. The airflow guiding duct includes two side panels and a connecting panel connecting the two side panels. A first opening is defined by a lower edge of the connecting panel and lower edges of the two side panels corresponding to the first heat generating element. The lower edges of the two side panels and the lower edge of the connecting panel are in the same plane. The first opening is a predetermined distance from the circuit board and the airflow guiding duct is capable of allowing air flow from different directions.

Other advantages and novel features of the present invention will become more apparent from the following detailed description of an exemplary embodiment when taken in conjunction with the accompanying drawings, in which:

### BRIEF DESCRIPTION OF THE DRAWINGS

FIG. 1 is an exploded, isometric view of an electronic device with an airflow guiding duct in accordance with an exemplary embodiment;

FIG. 2 is an isometric view of the airflow guiding duct in FIG. 1, but viewed from another aspect; and

FIG. 3 is an assembled view of the FIG. 1.

### DETAILED DESCRIPTION OF THE EMBODIMENT

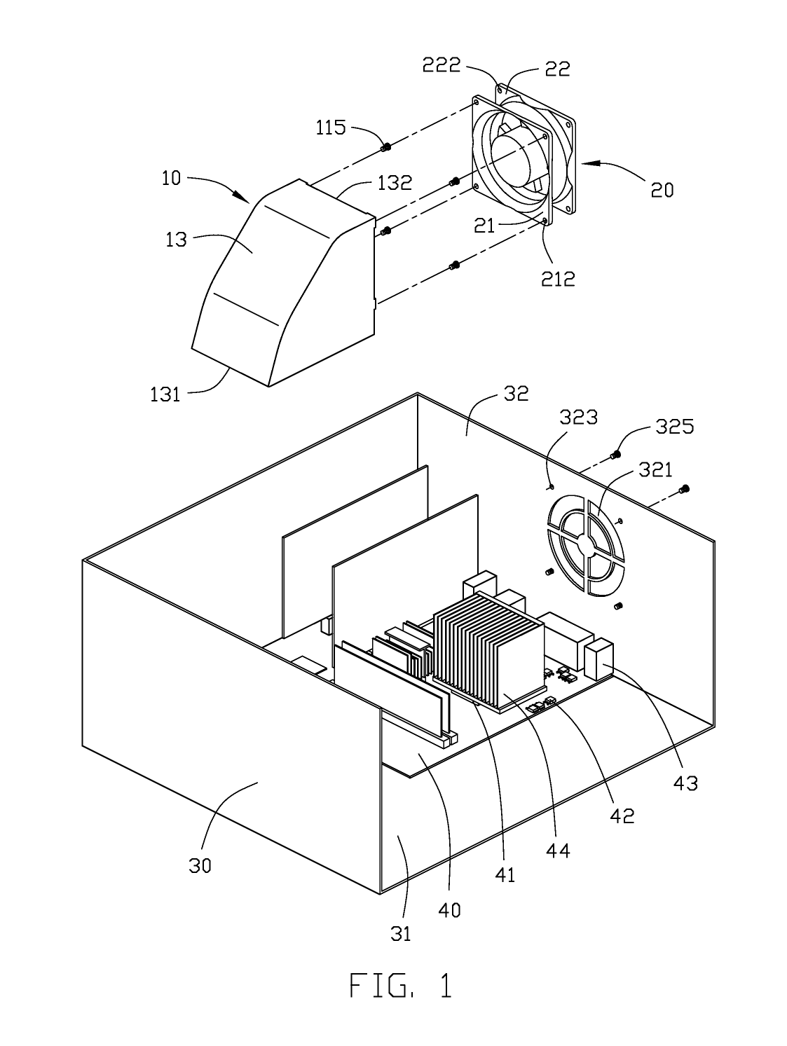

Referring to FIG. 1, an electronic device with an airflow guiding duct in accordance with the present invention includes an airflow guiding duct 10, a fan 20, an enclosure 30, and a motherboard 40 mounted in the enclosure 30.

The fan 20 includes a front panel 21 and a rear panel 22. The front panel 21 and the rear panel 22 each define four screw holes 212 and 222 at four corners thereof respectively.

The enclosure 30 includes a bottom wall 31 and a rear wall 32 perpendicular to the bottom wall 11. The rear wall 32 defines an opening 321 and four securing holes 323 near the opening 321 corresponding to the screw holes 222 of the rear panel 22 of the fan 20.

The motherboard 40 is mounted on the bottom wall 31 abutting the rear wall 32. The motherboard 40 includes a CPU 41 and a plurality of components 42 around the CPU 41 thereon. A heat sink 44 is mounted on the CPU 41. A plurality of connectors 43 is mounted on the motherboard 40 near to the rear wall 32 of the enclosure 30.

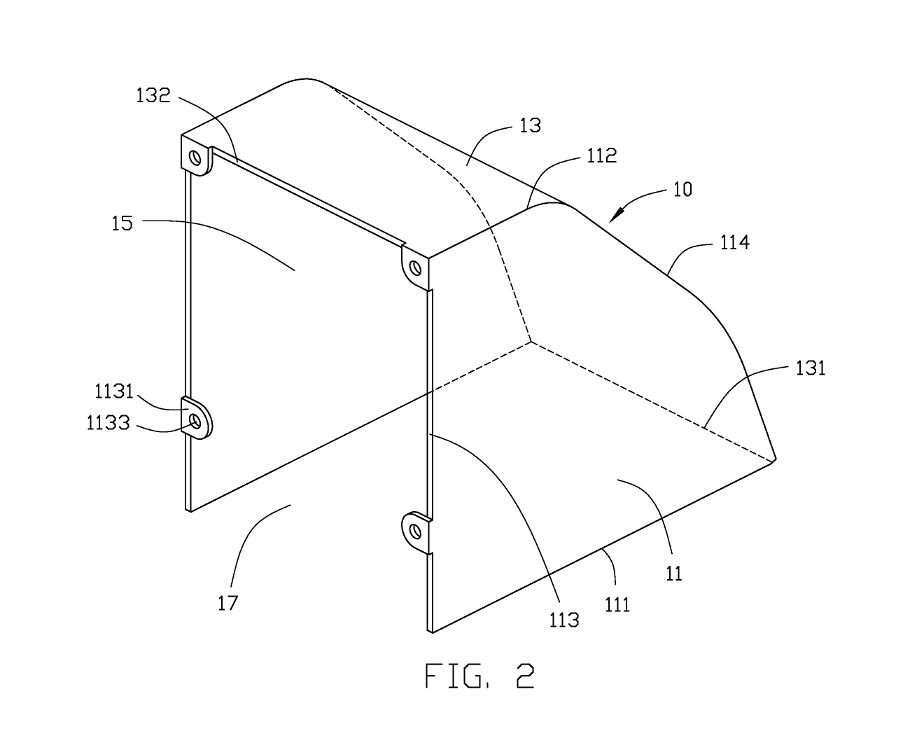

Referring to FIGS. 1 and 2, the airflow guiding duct 10 includes a pair of side panels 11 and a connecting panel 13. Each of side panels 11 includes an upper edge 112 and a lower edge 114. The connecting panel 13 connects the upper edge 112 and the lower edges 114 of one side panel 11 to the corresponding edges of the other side panel 11. An input opening 17 is defined by lower edges 111 of the pair of side panels 11 and a lower edge 131 of the connecting panel 13. The lower edge 131 and the lower edges 111 of the pair of side panels 11 are in the same plane. An output opening 15 is defined by the other pair of straight side edges 113 of the side panels 11 and an upper edge 132 of the connecting panel 13 corresponding to the front panel 21 of the fan 20. The input opening 17 and the output opening 15 are perpendicular to each other. The side edges 113 of the side panels 11 are perpendicular to the lower edges 111 of the side panels 11. The length of the upper edge 112 is less than that of the lower edge 111 of each side panel 11. A pair of securing clips 1131 extends from the side edge 113 of each side panel 11. Each securing clip 1131 defines a through hole 1133 corresponding to the screw hole 212 of the front panel of the fan 20.

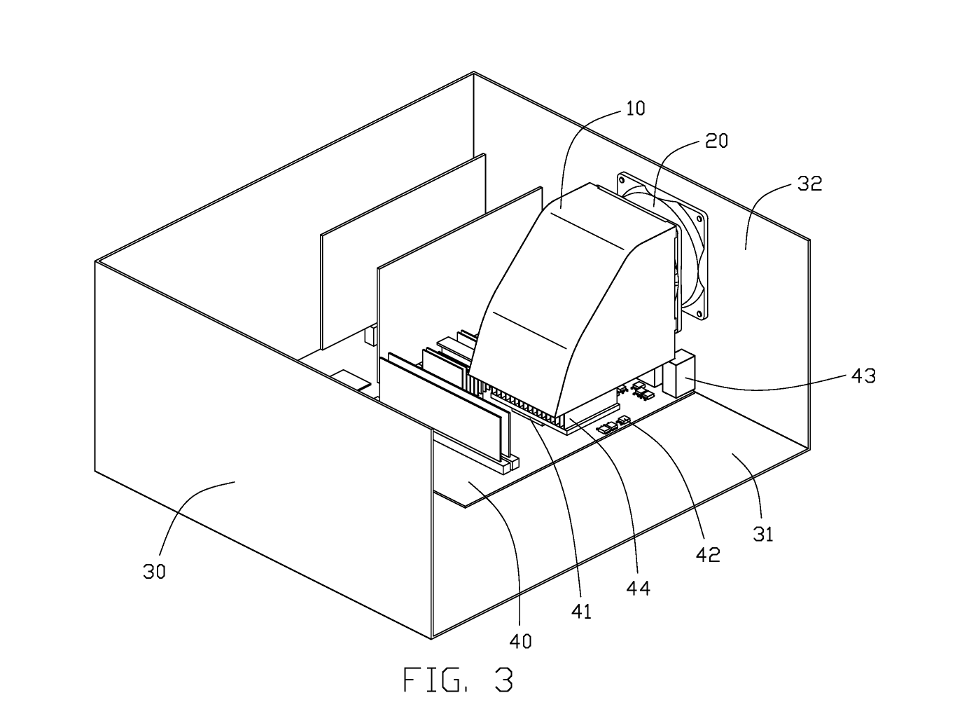

Referring to FIGS. 1 to 3, in assembly, four screws 325 extend respectively through the securing holes 323 of the rear wall 32 of the enclosure 30 and the screw holes 222 of the rear panel 22 of the fan 20 to secure the fan 20 on the rear wall 32 of the enclosure 30. Four screws 115 extend respectively through the screw holes 212 of the front panel 21 of the fan 20 and the through holes 1133 of the airflow guiding duct 10 to secure the fan 20 and the airflow guiding duct 10 together with the output opening 15 corresponding to the fan 20. The airflow guiding duct 10 receives the heat sink 40 therein via the input opening 17. The lower edges 111 of the side panels 11 of the airflow guiding duct 10 are set a distance from the motherboard 40 for allowing air to flow into the airflow guiding duct 10 via the input opening 17 from different directions, which enables heat generated by the CPU 41 and the components 42 around the CPU 41 to be dissipated efficiently.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device, comprising:
an enclosure comprising a bottom wall and a rear wall perpendicular to the bottom wall;
a circuit board mounted on the bottom wall of the enclosure, the circuit board comprising a first heat generating element and a second heat generating element near to the first heat generating element; and
an airflow guiding duct; wherein the airflow guiding duct comprises two side panels, a connecting panel that connects the two side panels and a first opening defined by the lower edge of the connecting panel and the lower edges of the two side panels, wherein the lower edges of the two side panels and the lower edge of the connecting panel are in the same plane, and the first opening is configured to correspond with the first heat generating element;
wherein the first opening is a predetermined distance from the circuit board and the airflow guiding duct is capable of allowing air flow from different directions.

2. The electronic device as described in claim 1, wherein the electronic device further comprises a fan;
wherein the airflow guiding duct comprises a second opening defined by an upper edge of the connecting panel the other pair of side edges of the side panels is configured to align with the fan.

3. The electronic device as described in claim 2, wherein the lower edges of the side panels are perpendicular to the other pair of side edges of the side panels.

4. The electronic device as described in claim 2, wherein the fan comprises a front panel defining a plurality of screw holes therein, and the airflow guiding duct further comprises a plurality of securing clips comprising of through holes;
wherein the through holes are configured to correspond with the screw holes.

5. The electronic device as described in claim 1, wherein the length of the upper edge of each side panel is less than that of the lower edge of each side panel.

6. The electronic device as described in claim 1, wherein a heat sink is mounted on the first heating generating element and the airflow guiding duct is capable of receiving the heat sink within the first opening.

7. An electronic device, comprising:
an enclosure comprising a bottom wall and a rear wall perpendicular to the bottom wall, the rear wall defining an opening;
a fan secured on the rear wall of the enclosure and aligned with the opening of the rear wall of the enclosure;
a circuit board mounted on the bottom wall of the enclosure, the circuit board comprising a first heat generating element and a second heat generating element near to the first heat generating element; and
an airflow guiding duct, wherein the airflow guiding duct comprises a first opening aligned with the fan and a second opening aligned with the first heat production, wherein the first opening is a predetermined distance from the circuit board and the airflow guiding duct is capable of allowing air flow from different directions.

8. The electronic device as described in claim 7, wherein the airflow guiding duct comprising two side panels and a connecting panel connecting a pair of side edges of the two side panels.

9. The electronic device as described in claim 8, wherein the first opening is defined by a lower edge of the connecting panel and lower edges of the two side panels, and the second opening is defined by an upper edge of the connecting panel the other pair of side edges of the side panels.

10. The electronic device as described in claim 8, wherein the length of the upper edge of each side panel is less than that of the lower edge of each side panel.

11. The electronic device as described in claim 8, wherein the length of the upper edge of each side panel is less than that of the lower edge of each side panel.

12. The electronic device as described in claim 8, wherein the fan comprises a front panel defining a plurality of screw holes therein, and the airflow guiding duct further comprises a plurality of securing clips comprising through holes;
wherein the through holes are configured to correspond with the screw holes.

13. A cooling system for a computer system comprising:
an airflow guiding duct and a fan;
wherein the duct comprises a first and second opening, the first opening is configured to receive a heat sink such that duct is able to encompass part of the heat sink;
the fan comprises a first and a second engagement surface; the first engagement surface is secured to the duct, the second engagement surface is configured to be secured to computer chassis;
and wherein the duct is capable of hovering over a mother board when the duct only has contact with the first engagement surface.

14. The cooling system as described in claim 13, wherein first and second openings are not fully enclosed by the duct.

15. The cooling system as described in claim 13, wherein first and second openings are fully enclosed by the duct.

16. The cooling system as described in claim 13, wherein the duct and the first engagement portion are secured by fasteners and those fasteners are partially located within the second opening.

17. The cooling system as described in claim 13, wherein the duct and the first engagement portion are secured by fasteners and the second opening is free from fasteners.
